(19) United States
(12) Patent Application Publication
(10) Pub. No.: US 2008/0290783 A1
(43) Pub. Date: Nov. 27, 2008

(54) SELF-ASSEMBLED MONOLAYER FOR TUNING THE WORK FUNCTION OF METAL ELECTRODES

(75) Inventors: Yu-Tai Tao, Nankang Taipei (TW); Kun-Yang Wu, Nankang Taipei (TW); Ming-Chin Hung, Nankang Taipei (TW); Hung-Wei Huang, Nankang Taipei (TW)

Correspondence Address: WPAT, PC, 7225 BEVERLY ST., ANNANDALE, VA, 22003, US

(73) Assignee: Yu-Tai Tao, Taipei (TW)

(21) Appl. No.: 11/754,194

(22) Filed: May 25, 2007

(51) Int. Cl. C07C 323/00; H01B 5/00; H01J 1/62

(52) U.S. Cl. 313/498; 174/126.2; 568/61

(57) ABSTRACT

The present invention discloses a self-assembled monolayer with a general formula G¹-R-G², wherein G¹ is SH. R of the mentioned general formula comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms. G² is an electron-withdrawing group.

### BACKGROUND OF THE INVENTION

1. Field of the Invention

The present invention is generally related to a self-assembled monolayer, and more particularly to a self-assembled monolayer for tuning the work function of metal electrodes.

2. Description of the Prior Art

Display technology has extensively applied as a platform for man-machine communication and information display in various areas, such as business, industry, army, transportation, medicine, education, and entertainment. In the past half century, scientific and engineering researches are successively dedicated in display technology and also develop a variety of display technologies, one of which is organic electroluminescence (OEL) technology. The OEL technology has potential to become the next generation and the future most applicable display and lighting source.

Generally, the OEL device consists diode property and comprises organic light-emitting diodes (OLED) and polymer light-emitting diodes (PLED), according to the material categorization of the emissive layer. The development of the OLED technology started from the OLED device with high quantum efficiency and low driving voltage, fabricated by Tang and Vanslyke at Eastman Kodak Company in 1987. The specific characteristic of the OLED device is that the device emits light whenever electric current flows through and the color of light depends on the structure of the organic molecule. Thus, different structure results in emitting red, green, or blue light. Therefore, RGB pixels for full-color displaying can be achieved. The OLED device has the advantages of self-emitting, high contrast, quick response time, light-weighted, low power consumption, flexible, super wide viewing angle, and so forth and can be utilized in flat or curved displays for various electric appliances, various signs, indicators, commercial lighting for signboards, general interior lighting, and functional large area lighting, etc. Therefore, it becomes a hot research subject.

The working principle of OLED is based on electroluminescence. As a pair of excited charge carriers, one with positive charge and the other one with negative charge, carry out recombination to form an exciton, the energy of the exciton is released by a form of photon to emit light. The charge carrier with positive charge is called “hole”, while one with negative charge is called “electron”. FIG. 1 shows a schematic diagram illustrating the structure of a conventional OLED device. The basic OLED device comprises a cathode 110, an anode 150, and an organic emissive layer 130. Between the electrode and the organic emissive layer, a hole injection layer 140 and an electron transport layer 120 may be included to assist the OLED operation. The OLED device may further comprise a transparent substrate 160, on which the OLED device is provided. Referring to FIG. 1, the direction pointed by the arrow is the light emitting direction of the OLED device. As the OLED device is applied with a positive voltage, electric field is generated in the interior of the device and electrons and holes under the influence of the electric field are injected from the cathode and anode, respectively, and transported to the emissive layer. The electron and hole come across to each other at the emissive layer to thereby form an exciton. The exciton under the influence of the electric field transfers energy to the luminescent molecule so as to have the electron of the luminescent molecule transfer to an excited state. Finally, the excited electron releases energy by a form of photon and then is back to its ground state so as to complete the process of electroluminescence.

Since radiant recombination of charge carriers causes luminescence in an OLED device, the luminance efficiency of the device is strongly affected by the efficiency of injecting the carriers generated at the electrodes into organic material. In addition, the positive and negative carrier injection rates need to be balanced. Otherwise, the recombination ratio of carriers may be decreased and straight passing current may be generated in the organic layer to thereby generate heat. Thus, the lifetime of the device may be reduced. The carrier from the electrode has to overcome an energy barrier in order to be injected into organic material. For a hole, the energy barrier is the energy difference between the work function of the anode and the lowest unoccupied molecular orbital (LUMO) of the organic material contacting with the anode. For an electron, the energy barrier is the energy difference between the work function of the cathode and the highest occupied molecular orbital (HOMO) of the organic material contacting with the cathode. Therefore, matching proper electrodes with organic material can effectively reduce the energy barrier for carrier injection and considerably increase the efficiency of carrier injection.

The conventional OLED device is mostly with bottom-emitting design. The anode is a transparent electrode, such as ITO (indium tin oxide). Light needs to pass through the bottom glass substrate and the thin-film transistor (TFT) in order to be seen. However, part of the light is blocked by TFT and opaque conducting wires in the capacitor and thus aperture ratio and total light exit area are decreased. Recently, the top-emitting design for OLED device has been fruitfully researched. The top-emitting OLED device comprises a transparent cathode and an opaque metal anode. Light exits from the top and is not affected by the opaque members at the bottom. Therefore, the disadvantage of blocking light by the TFT circuit is improved. Thus, aperture ratio and total light exit area are increased to a great extent. However, one drawback needed to be conquered is that the common used metal anode, such as silver or aluminum, has good reflectance but low work function. The energy barrier for hole injection is thereby increased. Therefore, a technique to tune the work function of the above metal anode and also maintain the optical property (high reflectance) is eagerly needed for the industry.

### SUMMARY OF THE INVENTION

In light of the above background, in order to fulfill the requirements of the industry, the present invention provides a self-assembled monolayer for tuning the work function of metal electrodes and its application in fabricating a metal electrode with tunable work function and a top-emitting organic light-emitting diode (TEOLED).

One object of the present invention is to elevate the work function of the electrode in the above OLED by modifying the electrode of the OLED.

Another object of the present invention is to reduce the energy barrier of hole injection by modifying the anode of the OLED.

Another object of the present invention is to provide a metal electrode with tunable work function. The metal electrode with tunable work function can be implemented by providing a self-assembled monolayer on one side of the metal electrode to achieve the purpose of tuning the work function of the metal electrode.

Another object of the present invention is to provide a top-emitting organic light-emitting diode having metal electrodes with tunable work function. The top-emitting organic light-emitting diode uses the metal electrode with tunable work function according to the present invention as the anode and uses a transparent electrode as the cathode.

Accordingly, the present invention discloses a self-assembled monolayer for tuning the work function of metal electrodes, comprising a compound with a general formula G¹-R-G², where G¹ is SH. R of the mentioned general formula comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms. G² is an electron-withdrawing group.

### BRIEF DESCRIPTION OF THE DRAWINGS

FIG. 1 shows a schematic diagram illustrating the structure of the conventional OLED device; and

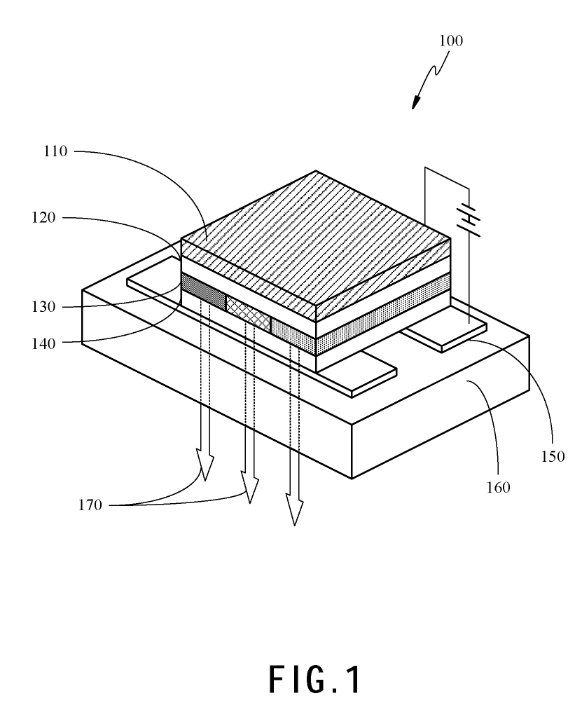

FIG. 2 shows a schematic diagram illustrating the device structure of the TEOLED according to the present invention.

### DESCRIPTION OF THE PREFERRED EMBODIMENTS

What is probed into the invention is a self-assembled monolayer for tuning the work function of metal electrodes. Detail descriptions of the processes and structures will be provided in the following in order to make the invention thoroughly understood. Obviously, the application of the invention is not confined to specific details familiar to those who are skilled in the art. On the other hand, the common processes and structures that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

In a first embodiment of the present invention, a self-assembled monolayer having a general formula G¹-R-G² is disclosed where G¹ is SH. R of the mentioned general formula comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms. G² is an electron-withdrawing group. In a preferred example of this embodiment, the G² comprises one selected from the group consisting of the following: CN, F, Cl, Br, CFH₂, CF₂H, CF₃, CClH₂, CCl₂H, CCl₃, CBrH₂, CBr₂H, CBr₃, NO, and NO₂.

In a second embodiment of the present invention, a metal electrode with tunable work function is disclosed. The metal electrode with tunable work function comprises a base metal electrode and a self-assembled monolayer provided on one side of the metal electrode. The self-assembled monolayer comprises a compound with a general formula G¹-R-G², where G¹ is SH. R of the mentioned general formula comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms. G² is an electron-withdrawing group. In a preferred example of this embodiment, the G² comprises one selected from the group consisting of the following: CN, F, Cl, Br, CFH₂, CF₂H, CF₃, CClH₂, CCl₂H, CCl₃, CBrH₂, CBr₂H, CBr₃, NO, and NO₂. In another preferred example of this embodiment, the base metal electrode is a silver electrode.

In this embodiment, the method for forming the metal electrode with tunable work function, comprises: (1) depicting a required electrode circuit pattern on an area of 0.625 mm² of a soda glass by the photo-mask technique and thermal evaporating silver to form a silver layer with thickness of 150 nm; and (2) immersing the silver substrate into an electrode modification solution with concentration of 1 mM for 2 hrs. The solvent for the electrode modification solution can be an organic solvent, such as ethanol, isopropyl alcohol, n-hexane, or other polar or nonpolar organic solvent known to those who are skilled in the art. The solute of the electrode modification solution comprises the compound with a general formula G¹-R-G², disclosed in this embodiment. In a preferred example of this embodiment, the solute has the following structure.

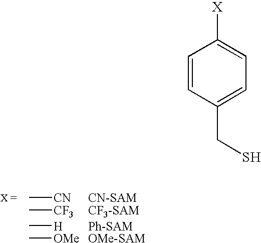

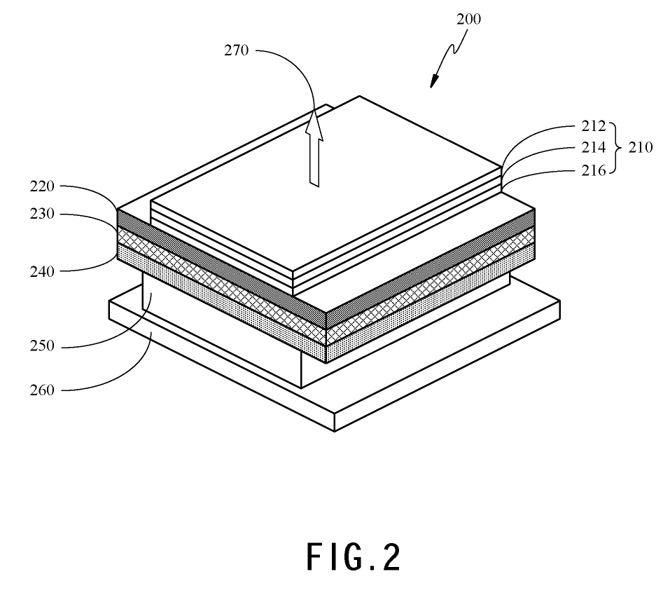

In a third embodiment of the present invention, a top-emitting organic light-emitting diode (TEOLED) with a metal electrode having the tunable work function is disclosed. FIG. 2 shows a schematic diagram illustrating the device structure of the TEOLED according to the present invention. As shown in the figure, the structure of the TEOLED comprises a first electrode 250, a hole injection layer 240, a hole transport layer 230, an electron transport layer 220, and a second electrode 210, sequentially from top to bottom.

The first electrode 250 can be the anode of the TEOLED, a metal electrode with tunable work function. The first electrode 250 comprises a self-assembled monolayer, not shown in the figure, provided on one side of the first electrode 250. The self-assembled monolayer comprises a compound with a general formula G¹-R-G², where G¹ is SH. R of the mentioned general formula comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms. G² is an electron-withdrawing group. In a preferred example of this embodiment, the G² comprises one selected from the group consisting of the following: CN, F, Cl, Br, CFH₂, CF₂H, CF₃, CClH₂, CCl₂H, CCl₃, CBrH₂, CBr₂H, CBr₃, NO, and NO₂. In another preferred example of this embodiment, the first electrode 250 is a silver electrode. The structure of the TEOLED may further comprise a substrate 260 provided on the bottom of the first electrode 250. The material of the substrate 260 can be glass, polymeric fiber, or other substrate material known to those who are skilled in the art.

The composition of the hole injection layer 240 comprises m-MTDADA [4,4′,4″-tris(3-methylphenylphenylamino)triphenylamine] or other material having hole injecting property. The composition of the hole transport layer 230 comprises α-naphthylphenylbiphenyl diamine (NPB) or other material having hole transport property. The composition of the electron transport layer 220 comprises tris-(8-hydroxyquinoline)aluminum (Alq) or other material having electron transport property. In an example of this embodiment, the electron transport layer 220 is also an emissive layer. The second electrode 210 is the cathode of the TEOLED and is a transparent electrode. Referring to FIG. 2, the second electrode 210 comprises the LiF layer 216, Al layer 214, and Ag layer 212. It should be noted that in the above structure the anode, cathode, and emissive layer are the essential components for OLED. The hole injection layer and the hole transport layer are not essential components but are used to promote the luminance efficiency of the OLED device and optimize the performance of the TEOLED provided by this embodiment. In addition, the compositions for the first electrode, the hole injection layer, the hole transport layer, the electron transport layer, and the second electrode described in the above are only examples in order to illustrate this embodiment. The scope of the present invention is based on the following claims of the invention and is not limited by the above description.

Referring to the following figure, the comparison result of the current density vs. voltage curves of the TEOLED provide by the preferred example of the invention with other control groups is shown.

In this example, the TEOLED provided by the present invention uses a silver electrode covered with a self-assembled monolayer with the electron-withdrawing group, CN and CF₃, as the anode. Besides, as shown in the figure, other control groups, for comparing purpose, use a pure silver electrode (labeled as Ag in the figure), a silver electrode covered with Ag₂O (labeled as Ag₂O/Ag in the figure), a silver electrode covered with a self-assembled monolayer without any substituted group (labeled as Ph-SAM/Ag in the figure), a silver electrode covered with a self-assembled monolayer with the electron-pushing group, OMe (labeled as OMe-SAM/Ag in the figure), and an ITO transparent electrode for a conventional bottom emitting organic light-emitting diode (BEOLED) (labeled as ITO in the figure) as the anode. The measurement result shows that the TEOLED having the silver electrode covered with a self-assembled monolayer with the CN electron-withdrawing group or the silver electrode covered with a self-assembled monolayer with the CF₃ electron-withdrawing group does have high current density, compared to other control groups. The only exception is the one having the silver electrode covered with Ag₂O. However, the Ag₂O layer covered on the silver electrode reduces the reflectance of the silver and thus it limits the usability as the anode of the TEOLED. Moreover, the physical property of Ag₂O is unstable to light and heat. Therefore, according to the implementation of the present invention, the self-assembled monolayer does not result in decrease of the reflectance of the silver electrode. Thus, the present invention not only tunes the work function of the silver electrode but also has more extensive industrial application.

Referring to the following figure, the measurement result of the current efficiency vs. current density curves of the above examples together with other control groups is shown.

The experiment groups, the silver electrode covered with a self-assembled monolayer with the CN electron-withdrawing group and the silver electrode covered with a self-assembled monolayer with the CF₃ electron-withdrawing group, and the control group having the silver electrode covered with Ag₂O have much higher efficiency than those of the other control groups including the conventional bottom-emitting OLED. According to the above-mentioned same reason, the silver electrode covered with Ag₂O affects the reflectance and also Ag₂O is unstable to light and heat. Thus, it limits the usability as the opaque anode for TEOLED.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A self-assembled monolayer for tuning the work function of metal electrodes, comprising: a compound with a general formula G¹-R-G², wherein
G¹ is SH;
R comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms; and
G² is an electron-withdrawing group.

2. The monolayer according to claim 1, wherein G² comprises one selected from the group consisting of the following: CN, F, Cl, Br, CFH₂, CF₂H, CF₃, CClH₂, CCl₂H, CCl₃, CBrH₂, CBr₂H, CBr₃, NO, and NO₂.

3. A metal electrode with tunable work function, comprising:
a metal electrode; and
a self-assembled monolayer provided on one side of said metal electrode wherein said self-assembled monolayer comprises a compound with a general formula G¹-R-G², in which
G¹ is SH;
R comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms; and
G² is an electron-withdrawing group.

4. The metal electrode according to claim 3, wherein G² comprises one selected from the group consisting of the following: CN, F, Cl, Br, CFH₂, CF₂H, CF₃, CClH₂, CCl₂H, CCl₃, CBrH₂, CBr₂H, CBr₃, NO, and NO₂.

5. The metal electrode according to claim 3, wherein said metal electrode is a silver electrode.

6. A top emitting organic light emitting diode (TEOLED) with a metal electrode having tunable work function, comprising:
an anode;
a self-assembled monolayer provided on one side of said anode wherein said self-assembled monolayer comprises a compound with a general formula G¹-R-G², in which
G¹ is SH;
R comprises one or any combination selected from the group consisting of the following: unsubstituted linear, branched, or cyclic alkyl moiety; single or multi-substituted linear, branched, or cyclic alkyl moiety with substituent selected from the group consisting of alkene and alkyne; aromatic group; multiple fused ring group; and multiple fused ring group with heteroatoms; and
G² is an electron-withdrawing group;
an organic emissive layer, provided on said self-assembled monolayer; and
a cathode provided on said organic emissive layer.

7. The organic light emitting diode according to claim 6, wherein G² comprises one selected from the group consisting of the following:
CN, F, Cl, Br, CFH₂, CF₂H, CF₃, CClH₂, CCl₂H, CCl₃, CBrH₂, CBr₂H, CBr₃, NO, and NO₂.

8. The organic light emitting diode according to claim 6, further comprising a hole injection layer (HIL).

9. The organic light emitting diode according to claim 6, further comprising a hole transport layer (HTL).

10. The organic light emitting diode according to claim 9, wherein the material of said hole transport layer comprises α-NPD (α-naphthylphenylbiphenyl diamine).

11. The organic light emitting diode according to claim 6, further comprising an electron transport layer (ETL).

12. The organic light emitting diode according to claim 6, wherein the material of said electron transport layer comprises Alq₃[tris-(8-hydroxyquinoline)aluminum].

13. The organic light emitting diode according to claim 12, wherein the material of said hole injection layer comprises one selected from the group consisting of the following: m-MTDADA [4,4′,4″-tris(3-methylphenylphenylamino)triphenylamine] and CuPc (copper phthalocyanine).

14. The organic light emitting diode according to claim 6, wherein said metal anode is a silver electrode.

15. The organic light emitting diode according to claim 6, wherein said metal cathode is a transparent electrode selected from the group consisting of one or any combination of the following: LiF, Al, and Ag.
